(19) United States
(12) Patent Application Publication
(10) Pub. No.: US 2026/0282907 A1
(43) Pub. Date: Sep. 17, 2026

(54) ADVANCED PACKAGING COMPONENT WITH HIGH THERMAL CONDUCTIVITY AND MANUFACTURING METHOD THEREOF

(71) Applicant: CMTEK Co., Ltd., Hsinchu County (TW)

(72) Inventors: CHIN-JUI LIANG, Hsinchu City (TW); Hao-Min Huang, Taoyuan City (TW)

(21) Appl. No.: 19/267,673

(22) Filed: Jul. 14, 2025

(30) Foreign Application Priority Data
Mar. 14, 2025 (TW) 114109516

(51) Int. Cl. H01L 23/373; H01L 21/48; H01L 23/00; H01L 23/367

(52) U.S. Cl. CPC H10W 40/254; H10W 40/22; H10W 70/027; H10W 74/15; H10W 90/724; H10W 90/734; H10W 90/736

(57) ABSTRACT

An advanced packaging component with high thermal conductivity and a manufacturing method thereof. The advanced packaging component includes a plate body and a three-dimensional thermal conductivity pattern. The plate body has a first surface and a second surface opposite to each other, and the plate body is formed of a high-rigidity material and has a heat source contact area. The three-dimensional thermal conductivity pattern is formed in the heat source contact area to form at least one thermal conductivity path between the first surface and the second surface. The three-dimensional thermal conductivity pattern is formed of a high thermal conductivity material, so that the at least one thermal conductivity path has a thermal conductivity coefficient greater than 500 W/mK.

### CROSS-REFERENCE TO RELATED PATENT APPLICATION

This application claims the benefit of priority to Taiwan Patent Application No. 114109516, filed on Mar. 14, 2025. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a semiconductor packaging component and a manufacturing method thereof, and more particularly to an advanced packaging component with high thermal conductivity and a manufacturing method thereof for being applied to advanced packaging such as chip-on-wafer-on-substrate (CoWoS) packaging.

### BACKGROUND OF THE DISCLOSURE

Advanced packaging is the integration of different systems into a same package. For example, different types of chips are integrated together through packaging and stacking technology to enhance the overall performance of semiconductor devices, including transmission speed, computing speed, etc., so as to reduce size and power consumption. However, with the development of advanced packaging technology, the uneven thermal stress caused by the interaction of multiple materials, various packaging parameter conditions (such as temperature, humidity, and pressure), package geometries, etc., can easily lead to thermal expansion coefficient (CTE) mismatch, warpage, delamination, peeling, cracking and other phenomena in the package.

### SUMMARY OF THE DISCLOSURE

In response to the above-referenced technical inadequacies, the present disclosure provides an advanced packaging component with high thermal conductivity and a manufacturing method thereof. The concept behind the present disclosure is to integrate the designed three-dimensional thermal conductivity pattern into a highly rigid structure according to practical heat dissipation requirements to form an inseparable integrated structure (an all-in-one structure). The three-dimensional thermal conductivity pattern can establish an uninterrupted and efficient thermal conductivity path between a chip and other interfaces. Such structure has excellent thermal and mechanical properties, and thus has good prospects across a broad range of applications in the field of advanced packaging.

In order to solve the above-mentioned problems, one of the technical aspects adopted by the present disclosure is to provide an advanced packaging component with high thermal conductivity, which includes a plate body and a three-dimensional thermal conductivity pattern. The plate body has a first surface and a second surface opposite to each other. The plate body is formed of a high-rigidity material and has a heat source contact area. The three-dimensional thermal conductivity pattern is formed in the heat source contact area to form at least one thermal conductivity path between the first surface and the second surface. The three-dimensional thermal conductivity pattern is formed of a high thermal conductivity material, so that the at least one thermal conductivity path has a thermal conductivity greater than 500 W/mK.

In one of the possible or preferred embodiments, the high-rigidity material is at least one of aluminum silicon carbide, wafer material, high-rigidity plastic, and high-rigidity metal material, and the high thermal conductivity material is at least one of diamond, diamond-like carbon, graphene, boron nitride, and high thermal conductivity alloy.

In one of the possible or preferred embodiments, the wafer material is silicon material, silicon carbide, or gallium nitride, the high-rigidity plastic is polyimide, and the high-rigidity metal material is molybdenum or nickel.

In one of the possible or preferred embodiments, the plate body has at least one through-hole located in the heat source contact area and penetrating the first surface and the second surface, and the three-dimensional thermal conductivity pattern includes at least one thermal conductivity column filled in the at least one through-hole.

In one of the possible or preferred embodiments, the at least one through-hole is a plurality of through-holes arranged in a row or in an array, and the at least one thermal conductivity column is a plurality of thermal conductivity columns respectively filled in the plurality of through-holes.

In one of the possible or preferred embodiments, the at least one thermal conductivity column is formed by stacking a plurality of diamond particles.

In one of the possible or preferred embodiments, a diameter of the at least one through-hole on the first surface is smaller than a diameter of the at least one through-hole on the second surface.

In one of the possible or preferred embodiments, the plate body has at least one groove located in the heat source contact area and penetrating through the first surface and the second surface, and the three-dimensional thermal conductivity pattern includes at least one thermal conductivity sheet embedded in the at least one groove. The at least one thermal conductivity sheet is in the shape of a long strip or a mesh.

In one of the possible or preferred embodiments, the at least one thermal conductivity sheet is a multi-layer mesh structure, and grids of an upper layer and a lower layer of the multi-layer mesh structure are alternately distributed.

In one of the possible or preferred embodiments, the plate body includes an aluminized silicon carbide substrate and an aluminum skin layer covering the aluminized silicon carbide substrate.

In one of the possible or preferred embodiments, the aluminized silicon carbide substrate includes a silicon carbide-based porous ceramic substrate and solid aluminum-based metal infiltrated and filled in pores of the silicon carbide-based porous ceramic substrate.

In one of the possible or preferred embodiments, the silicon carbide-based porous ceramic substrate is composed of small-sized particles, medium-sized particles, and large-sized particles, and the particle size ratio of the small-sized particles, the medium-sized particles, and the large-sized particles is 1:2-2.5:3-20.

In one of the possible or preferred embodiments, the particle size of the small-sized particles ranges from 0.1 μm to 5 μm, the particle size of the medium-sized particles ranges from 2 μm to 10 μm, and the particle size of the large-sized particles ranges from 10 μm to 100 μm.

In one of the possible or preferred embodiments, based on a total weight of the silicon carbide-based porous ceramic substrate, the weight ratio of the small-sized particles, the medium-sized particles, and the large-sized particles is 1:3:4.

In order to solve the above-mentioned problems, another one of the technical aspects adopted by the present disclosure is to provide a manufacturing method of the advanced packaging component with high thermal conductivity as described above, and the method includes: forming the high-rigidity material into a preform, forming the high thermal conductivity material into the three-dimensional thermal conductivity pattern, and arranging the three-dimensional thermal conductivity pattern into the preform; and pressing and sintering the preform having the three-dimensional thermal conductivity pattern arranged therein.

Therefore, in the advanced packaging component with high thermal conductivity provided by the present disclosure, by virtue of technical features of “the plate body being formed of a high-rigidity material and having a heat source contact area,” “the three-dimensional thermal conductivity pattern being formed in the heat source contact area to form at least one thermal conductivity path between the first surface and the second surface,” and “the three-dimensional thermal conductivity pattern being formed of a high thermal conductivity material, so that the at least one thermal conductivity path has a thermal conductivity coefficient greater than 500 W/mK,” the chip heat dissipation requirements of advanced packaging can be met, and process simplification, yield improvement, and cost reduction can be achieved.

Furthermore, the advanced packaging component with high thermal conductivity provided by the present disclosure can have many excellent properties, including high-rigidity, high thermal conductivity, high strength, and good thermal dimensional stability, and is very suitable for application in advanced packaging architectures of one or more semiconductor chips (semiconductor dies).

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic perspective view of an advanced packaging component with high thermal conductivity according to a first embodiment of the present disclosure;

FIG. 2A and FIG. 2B are schematic cross-sectional views taken along line II-II of FIG. 1;

FIG. 3 is a schematic view showing a structural change of FIG. 2A;

FIG. 4 is an enlarged schematic view of portion IV of FIG. 3;

FIG. 5 is another schematic perspective view of the advanced packaging component with high thermal conductivity according to the first embodiment of the present disclosure;

FIG. 6 is a schematic cross-sectional view taken along line VI-VI of FIG. 5;

FIG. 7 is a schematic cross-sectional view taken along line VII-VII of FIG. 5;

FIG. 8 is yet another schematic perspective view of the advanced packaging component with high thermal conductivity according to the first embodiment of the present disclosure;

FIG. 9 is a schematic cross-sectional view taken along line IX-IX of FIG. 8;

FIG. 10 is a schematic view of the structure of a plate body of the advanced packaging component with high thermal conductivity according to the first embodiment of the present disclosure;

FIG. 11 is an enlarged schematic view of part XI of FIG. 10;

FIG. 12 is a schematic diagram of a packaging structure including the advanced packaging component with high thermal conductivity according to the first embodiment of the present disclosure;

FIG. 13 is a schematic partial perspective view of the advanced packaging component with high thermal conductivity according to a second embodiment of the present disclosure;

FIG. 14 is a schematic diagram of the packaging structure including the advanced packaging component with high thermal conductivity according to a third embodiment of the present disclosure; and

FIG. 15 is a flowchart of a manufacturing method of the advanced packaging component with high thermal conductivity according to one embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

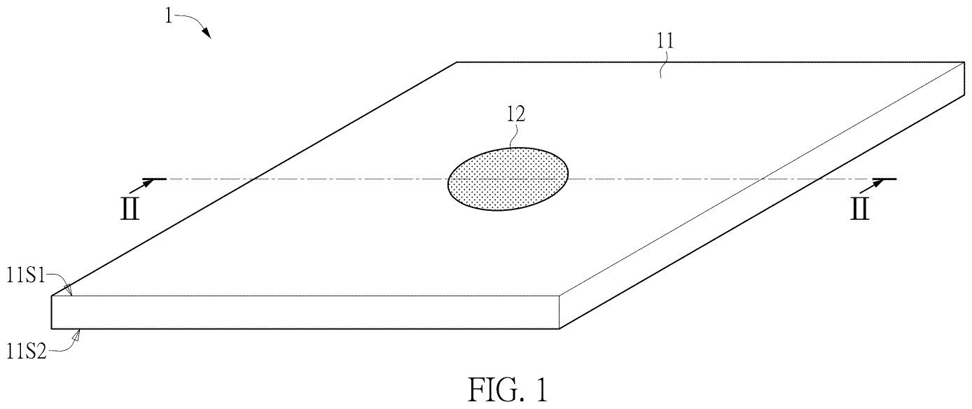

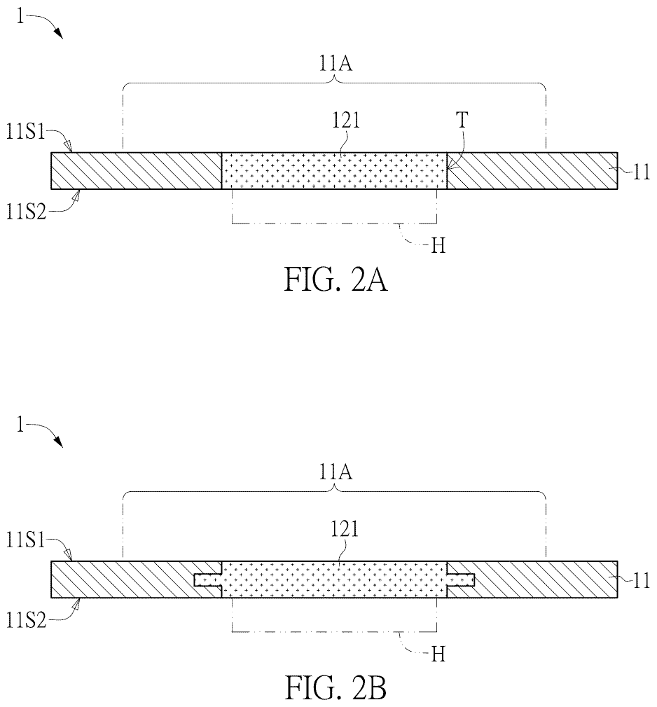

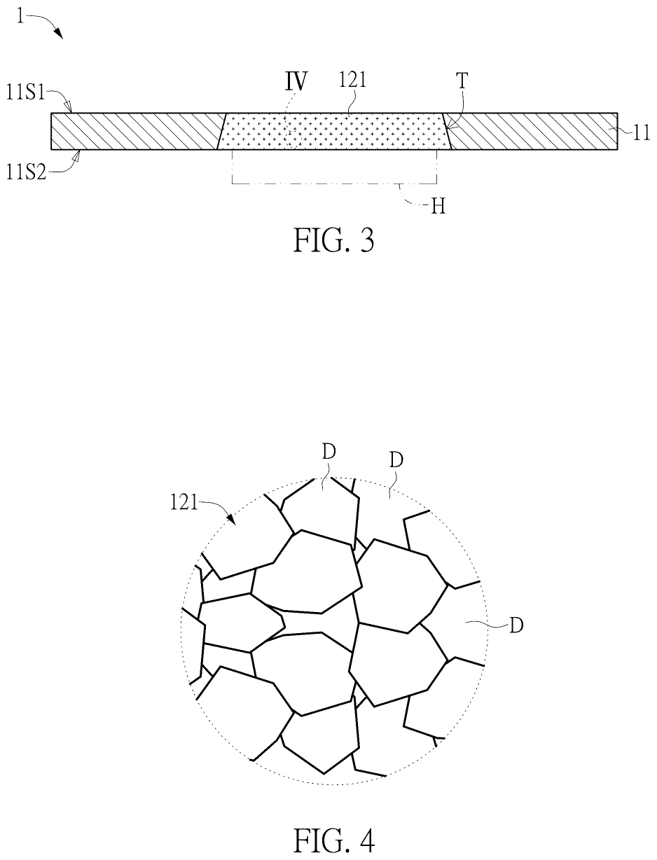

Referring to FIG. 1 to FIG. 3, FIG. 1 shows an advanced packaging component with high thermal conductivity 1 according to a first embodiment of the present disclosure, and FIG. 2A, FIG. 2B, and FIG. 3 show technical features of the advanced packaging component 1 in one implementation of the first embodiment of the present disclosure. As shown in the above figures, the first embodiment of the present disclosure provides an advanced packaging component 1, which includes a plate body 11 and a three-dimensional thermal conductivity pattern 12. The plate body 11 has a heat source contact area 11A for maintaining thermal contact with a heat source H (e.g., a semiconductor wafer). The three-dimensional thermal conductivity pattern 12 is formed in the heat source contact area 11A to form at least one thermal conductivity path between a first surface 11S1 (such as an upper surface) and a second surface 11S2 (such as a lower surface) of the plate body 11, which can efficiently conduct heat from the heat source H to the external environment or a heat sink, such that the heat generated by the heat source H is dissipated.

In the present disclosure, the plate body 11 is formed of a high-rigidity material. The three-dimensional thermal conductivity pattern 12 is formed of a high thermal conductivity material and is distributed in the heat source contact area 11A to form an integrated composite material structure with the plate body 11. Compared with traditional packaging components made of metal materials, the above-mentioned composite material structure has better thermal and mechanical properties, and thus has greater application prospects in the field of advanced packaging. It should be noted that the thermal conductivity (a K value) of the at least one thermal conductivity path composed of the three-dimensional thermal conductivity pattern 12 can reach above 500 W/mK, preferably from 500 W/mK to 2000 W/mK.

According to practical requirements, the thermal conductivity (the K value) of the thermal conductivity path composed of the three-dimensional thermal conductivity pattern 12 can be 500 W/mK, 600 W/mK, 700 W/mK, 800 W/mK, 900 W/mK, 1000 W/mK, 1100 W/mK, 1200 W/mK, 1300 W/mK, 1400 W/mK, 1500 W/mK, 1600 W/mK, 1700 W/mK, 1800 W/mK, 1900 W/mK, or 2000 W/mK.

The high-rigidity material applicable to the present disclosure may be at least one of aluminum silicon carbide, wafer material, high-rigidity plastic, and high-rigidity metal material; the wafer material is preferably silicon material, silicon carbide, or gallium nitride; the high-rigidity plastic is preferably polyimide (PI); and the high-rigidity metal material is preferably molybdenum or nickel. The high thermal conductivity material applicable to the present disclosure may be at least one of diamond, diamond-like carbon, graphene, boron nitride, and high thermal conductivity alloy; here, the high thermal conductivity alloy may contain copper, molybdenum, cobalt, and/or radium.

In this embodiment, the plate body 11 has at least one through-hole T located in the heat source contact area 11A and penetrating the first surface 11S1 and the second surface 11S2, and the three-dimensional thermal conductivity pattern 12 includes at least one thermal conductivity column 121 (such as a column-shaped diamond structure) filled in the at least one through-hole T. In practical applications, laser processing (such as laser drilling) or mechanical processing (such as mechanical drilling) can be used to form the through-hole T on the plate body 11, and the configuration of the through-hole T can be regulated by controlling the processing conditions. For example, the through-hole T can be formed to have a substantially uniform aperture, as shown in FIG. 1; alternatively, the through-hole T can be formed to have an aperture that gradually decreases along a thickness direction of the plate body 11, as shown in FIG. 2A.

As shown in FIG. 4, the thermal conductivity column 121 may be formed by closely stacking a plurality of diamond particles D, and the plurality of diamond particles D may be sintered at a high temperature to form a large number of diamond bonds between each other, thereby obtaining a diamond structure with a high stacking density.

In addition, as shown in FIG. 2B, the thermal conductivity column 121 can be positioned in the through-hole T by means of a concave-convex engagement.

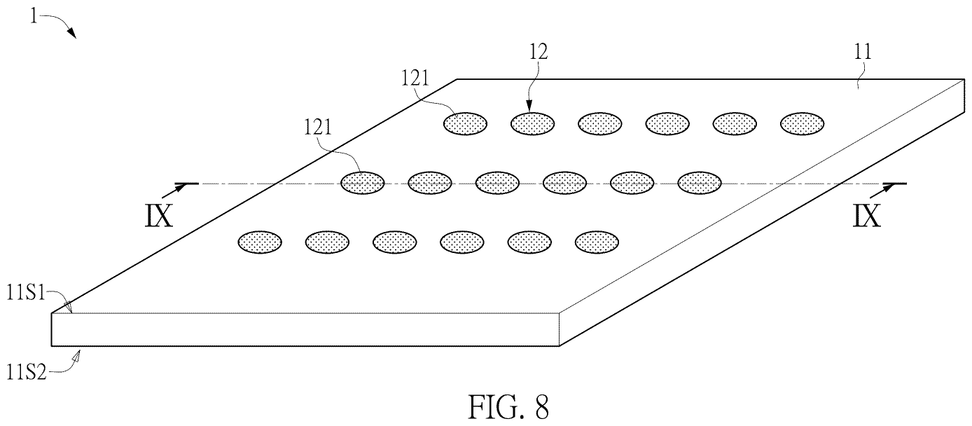

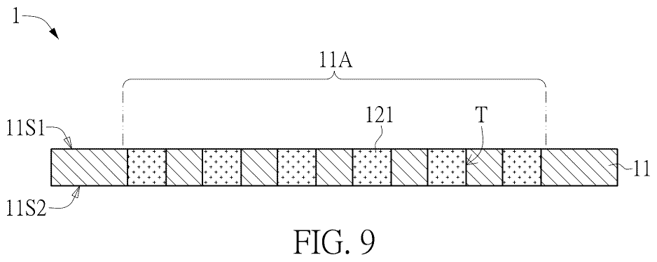

FIG. 8 and FIG. 9 show technical features of another implementation of the advanced packaging component 1 according to the first embodiment of the present disclosure. As shown in FIG. 8 and FIG. 9, according to actual heat dissipation requirements (such as heat dissipation requirements for a larger area), the through-hole T and the thermal conductivity column 121 can be plural in number. Specifically, multiple through-holes T can be arranged in an array in the heat source contact area 11A; and multiple thermal conductivity columns 121 are respectively filled in the multiple through-holes T; here, each of the thermal conductivity columns 121 can completely fill a corresponding one of the through-holes T, such that two ends of each of the thermal conductivity columns 121 are respectively exposed from the first surface 11S1 and the second surface 11S2 of the plate body 11. However, the above description is only one feasible implementation and is not intended to limit the present disclosure. For example, a plurality of through-holes T may also be arranged in a row in the heat source contact area 11A.

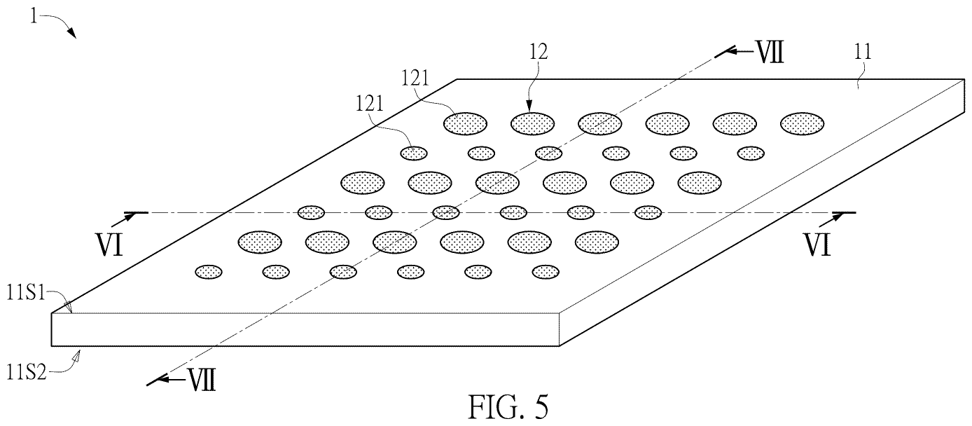

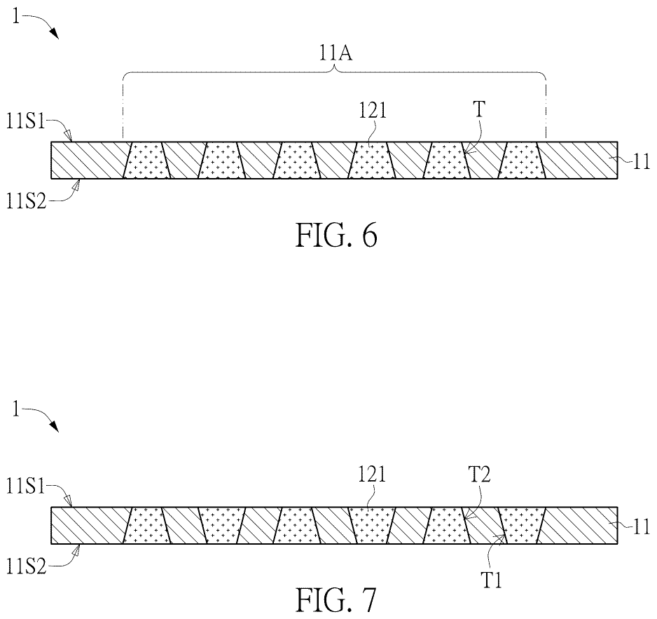

FIG. 5 to FIG. 7 illustrate technical features of yet another implementation of the advanced packaging component 1 according to the first embodiment of the present disclosure. As shown in FIG. 5 to FIG. 7, the plurality of through-holes T may include a plurality of first through-holes T1 and a plurality of second through-holes T2 having different configurations, and the plurality of first through-holes T1 and the plurality of second through-holes T2 are alternately arranged. Specifically, each of the first through-holes T1 has a diameter that gradually decreases from the first surface 11S1 of the plate body 11 to the second surface 11S2, and each of the second through-holes T2 has a diameter that gradually decreases from the second surface 11S2 of the plate body 11 to the first surface 11S1. Therefore, the at least one thermal conductivity path composed of the three-dimensional thermal conductivity pattern 12 can uniformly dissipate heat along the thickness direction of the plate body 11.

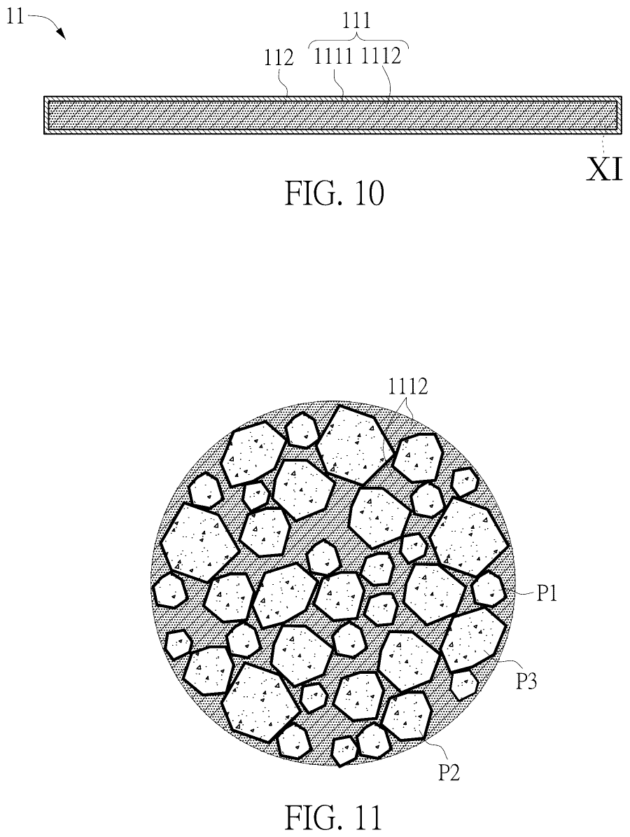

Referring to FIG. 10 and FIG. 11, considering the thermal and mechanical properties, the plate body 11 may be made of aluminum silicon carbide and formed by ways of a gas phase or liquid phase infiltration. Specifically, the plate body 11 may include an aluminized silicon carbide substrate 111 and an aluminum skin layer 112 covering the aluminized silicon carbide substrate 111. The aluminized silicon carbide substrate 111 includes a silicon carbide-based porous ceramic substrate 1111 and solid aluminum-based metal 1112 infiltrated and filled in pores of the silicon carbide-based porous ceramic substrate 1111. In addition, the aluminum skin layer 112 can be formed by depositing the melt or vapor of aluminum-based metal to adhere to the outer surface of the silicon carbide-based porous ceramic substrate 1111. Here, the aluminum skin layer 112 can fully cover the outer surface of the silicon carbide-based porous ceramic substrate 1111.

Since the plate body 11 has the above-mentioned technical features, the advanced packaging component 1 of the present disclosure has many excellent properties, including high-rigidity, high thermal conductivity, high strength, and good thermal dimensional stability, and is very suitable for application in the advanced packaging architecture of one or more semiconductor chips (semiconductor dies) to solve the problems of mismatch in thermal expansion coefficients, warping, delamination and peeling, cracking, etc., between different materials caused by the increase in the size of advanced packaging.

As shown in FIG. 11, the silicon carbide-based porous ceramic substrate 1111 can be composed of small-sized particles P1, medium-sized particles P2, and large-sized particles P3, and has a porosity of from 20% to 70%. The particle size ratio of the small-sized particles P1, the medium-sized particles P2, and the large-sized particles P3 can be 1:2-2.5:3-20. In practical applications, the particle size of the small-sized particles P1 may be in the range of from 0.1 μm to 5 μm, the particle size of the medium-sized particles P2 may be in the range of from 2 μm to 10 μm, and the particle size of the large-sized particles P3 may be in the range of from 10 μm to 100 μm. Preferably, based on a total weight of the silicon carbide-based porous ceramic substrate 1111, the weight ratio of the small-sized particles P1, the medium-sized particles P2, and the large-sized particles P3 is 1:3:4.

It should be noted that, as the size (e.g., thickness) of the silicon carbide-based porous ceramic substrate 1111 changes, the particle sizes of the small-sized particles P1, the medium-sized particles P2, and the large-sized particles P3 will increase or decrease according to the above ratio. In addition, the small-sized particles P1, the medium-sized particles P2, and the large-sized particles P3 can be connected together by sintering or bonding, and stacked together to form an integrated structure (such as a block or sheet structure).

In certain embodiments, the material of the silicon carbide-based porous ceramic substrate 1111 is substantially silicon carbide, and more than 99% of the small-sized particles P1, the medium-sized particles P2, and the large-sized particles P3 are silicon carbide particles. Therefore, the thermal conductivity of the silicon carbide-based porous ceramic substrate 1111 can be improved.

In certain embodiments, the material of the silicon carbide-based porous ceramic substrate 1111 includes silicon carbide and diamond, and less than 30% of the small-sized particles P1, the medium-sized particles P2, and the large-sized particles P3 are silicon carbide particles. Therefore, the moldability of the silicon carbide-based porous ceramic substrate 1111 can be improved.

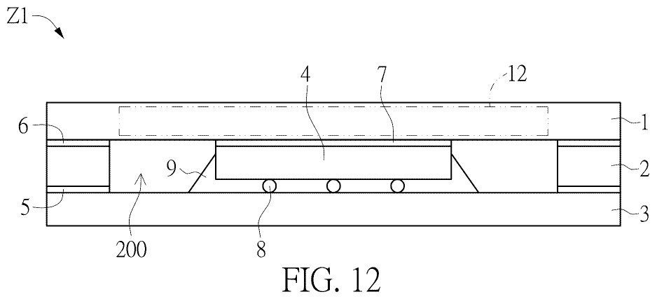

Reference is made to FIG. 12, which shows a packaging structure Z1 of the advanced packaging component 1 according to the first embodiment of the present disclosure. As shown in FIG. 12, the packaging structure Z1 includes the advanced packaging component 1 of the present disclosure, a ring component 2, a substrate 3, and a semiconductor chip 4. Specifically, the ring component 2 is disposed on the substrate 3, and the semiconductor chip 4 is bonded to the substrate 3 and is disposed in an accommodating area 200 of the ring component 2. The advanced packaging component 1 of the present disclosure is used as a cover component to be disposed on the ring component 2 and is located above the accommodating area 200 to cover the semiconductor chip 4.

In practical applications, the ring component 2 can be bonded to the substrate 3 via a first adhesive layer 5, and the advanced packaging component 1 of the present disclosure can be bonded to the ring component 2 via a second adhesive layer 6. In addition, the semiconductor chip 4 can be attached to the substrate 3 through an underfill layer 9 and electrically connected to the substrate 3 through a plurality of connecting bumps 8 (such as a plurality of solder bumps); the underfill layer 9 can be formed at a periphery of the semiconductor chip 4 and fill the gap between the semiconductor chip 4 and the substrate 3. Furthermore, a third adhesive layer 7 (such as a thermal interface material) can be provided between the advanced packaging component 1 and the semiconductor chip 4 of the present disclosure. However, the above-mentioned description is only one feasible implementation and is not intended to limit the present disclosure.

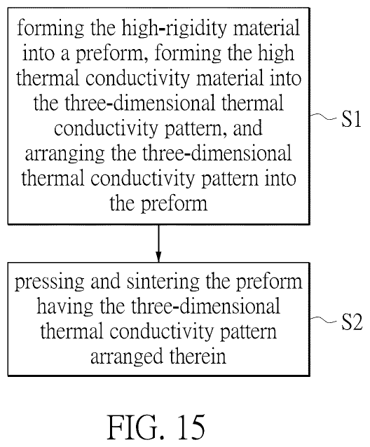

Reference is made to FIG. 15, which shows a manufacturing method for the advanced packaging component with high thermal conductivity 1 according to the first embodiment of the present disclosure, and the manufacturing method includes: step S1 of: forming the high-rigidity material into a preform, forming the high thermal conductivity material into the three-dimensional thermal conductivity pattern, and arranging the three-dimensional thermal conductivity pattern into the preform; and step S2 of: pressing and sintering the preform having the three-dimensional thermal conductivity pattern arranged therein.

### Second Embodiment

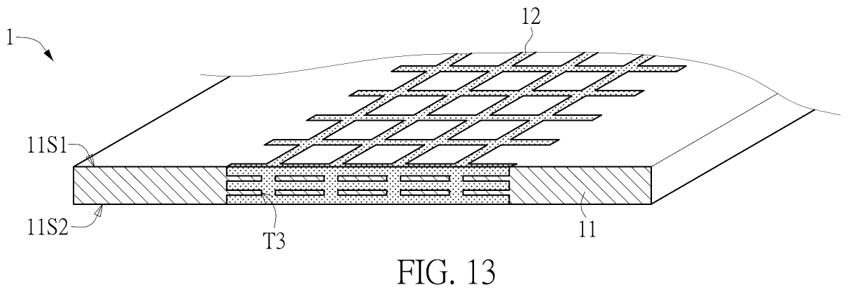

Reference is made to FIG. 13, which shows an advanced packaging component with high thermal conductivity 1 according to a second embodiment of the present disclosure. As shown in FIG. 13, the advanced packaging component 1 of the present disclosure includes a plate body 11 and a three-dimensional thermal conductivity pattern 12. In this embodiment, the plate body 11 has a first surface 11S1 and a second surface 11S2 opposite to each other, and the plate body 11 is formed of a high-rigidity material and has a heat source contact area 11A. The three-dimensional thermal conductivity pattern 12 is formed in the heat source contact area 11A to form at least one thermal conductivity path between the first surface 11S1 and the second surface 11S2 of the plate body 11. Here, the three-dimensional thermal conductivity pattern 12 is formed of a high thermal conductivity material, such that the at least one thermal conductivity path has a thermal conductivity greater than 500 W/mK.

A difference between this embodiment and the first embodiment is that, in this embodiment, the plate body 11 has at least one groove T3 located in the heat source contact area 11A and penetrating the first surface 11S1 and the second surface 11S2, and the three-dimensional thermal conductivity pattern 12 includes at least one thermal conductivity sheet 122 embedded in the at least one groove T3. Specifically, the at least one thermal conductivity sheet 122 may include one or more strip structures, and is preferably a mesh thermal conductivity sheet, such that the at least one thermal conductivity path composed of the three-dimensional thermal conductivity pattern 12 can uniformly dissipate heat along the thickness direction of the plate body 11.

The relevant technical details mentioned in the first embodiment remain valid in this embodiment and will not be reiterated herein to avoid redundancy. Accordingly, the relevant technical details mentioned in this embodiment can also be applied to the first embodiment.

### Third Embodiment

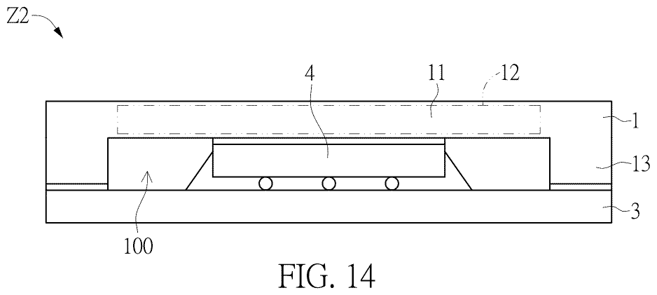

Reference is made to FIG. 14, which shows an advanced packaging component with high thermal conductivity 1 according to a third embodiment of the present disclosure. In this embodiment, the advanced packaging component 1 of the present disclosure includes a plate body 11, a three-dimensional thermal conductivity pattern 12, and a frame body 13. The plate body 11 and the frame body 13 are integrally formed by high-rigidity materials, the plate body 11 has a first surface 11S1 and a second surface 11S2 opposite to each other, and the frame body 13 is an extension portion from the second surface 11S2. In addition, the plate body 11 has a heat source contact area, and the three-dimensional thermal conductivity pattern 12 is formed in the heat source contact area to form at least one thermal conductivity path between the first surface 11S1 and the second surface 11S2 of the plate body 11. The three-dimensional thermal conductivity pattern 12 is formed of a high thermal conductivity material, such that at least one thermal conductivity path has a thermal conductivity greater than 500 W/mK.

FIG. 14 further shows a packaging structure Z2 including the advanced packaging component 1 according to the third embodiment of the present disclosure. The packaging structure Z2 includes the advanced packaging component 1 according to the present disclosure, a substrate 3, and a semiconductor chip 4. Specifically, the advanced packaging component 1 of the present disclosure is disposed on a substrate 3, and the plate body 11 and the frame body 13 together form an accommodating area 100. The semiconductor chip 4 is disposed on the substrate 3 and arranged in the accommodating area 100 between the plate body 11 and the frame body 13.

The relevant technical details mentioned in the first and second embodiments remain valid in this embodiment and will not be reiterated herein to avoid redundancy. Accordingly, the relevant technical details mentioned in this embodiment can also be applied to the first and second embodiments.

### Beneficial Effects of the Embodiments

In conclusion, in the advanced packaging component with high thermal conductivity provided by the present disclosure, by virtue of technical features of “the plate body being formed of a high-rigidity material and having a heat source contact area,” “the three-dimensional thermal conductivity pattern being formed in the heat source contact area to form at least one thermal conductivity path between the first surface and the second surface,” and “the three-dimensional thermal conductivity pattern being formed of a high thermal conductivity material, so that the at least one thermal conductivity path has a thermal conductivity coefficient greater than 500 W/mK,” the chip heat dissipation requirements of advanced packaging can be met, and process simplification, yield improvement, and cost reduction can be achieved.

Furthermore, the advanced packaging component with high thermal conductivity provided by the present disclosure can have many excellent properties, including high-rigidity, high thermal conductivity, high strength, and good thermal dimensional stability, and is very suitable for application in advanced packaging architectures of one or more semiconductor chips (semiconductor dies).

Moreover, the advanced packaging component with high thermal conductivity provided by the present disclosure is applied to advanced packaging, which can effectively avoid the occurrence of thermal expansion coefficient mismatch, warping, delamination and peeling, cracking, etc., thereby improving the process yield and reducing costs.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An advanced packaging component with high thermal conductivity, comprising:
a plate body having a first surface and a second surface opposite to each other, wherein the plate body is formed of a high-rigidity material and has a heat source contact area; and
a three-dimensional thermal conductivity pattern formed in the heat source contact area to form at least one thermal conductivity path between the first surface and the second surface, wherein the three-dimensional thermal conductivity pattern is formed of a high thermal conductivity material, so that the at least one thermal conductivity path has a thermal conductivity coefficient greater than 500 W/mK.

2. The advanced packaging component according to claim 1, wherein the high-rigidity material is at least one of aluminum silicon carbide, wafer material, high-rigidity plastic, and high-rigidity metal material, and the high thermal conductivity material is at least one of diamond, diamond-like carbon, graphene, boron nitride, and high thermal conductivity alloy.

3. The advanced packaging component according to claim 2, wherein the wafer material is silicon material, silicon carbide, or gallium nitride, the high-rigidity plastic is polyimide, and the high-rigidity metal material is molybdenum or nickel.

4. The advanced packaging component according to claim 2, wherein the plate body has at least one through-hole located in the heat source contact area and penetrating the first surface and the second surface, and the three-dimensional thermal conductivity pattern includes at least one thermal conductivity column filled in the at least one through-hole.

5. The advanced packaging component according to claim 4, wherein the at least one thermal conductivity column is formed by stacking a plurality of diamond particles.

6. The advanced packaging component according to claim 4, wherein a diameter of the at least one through-hole on the first surface is smaller than a diameter of the at least one through-hole on the second surface.

7. The advanced packaging component according to claim 4, wherein the at least one through-hole is a plurality of through-holes arranged in a row or in an array, and the at least one thermal conductivity column is a plurality of thermal conductivity columns respectively filled in the plurality of through-holes.

8. The advanced packaging component according to claim 7, wherein the at least one thermal conductivity column is formed by stacking a plurality of diamond particles.

9. The advanced packaging component according to claim 7, wherein a diameter of the at least one through-hole on the first surface is smaller than a diameter of the at least one through-hole on the second surface.

10. The advanced packaging component according to claim 2, wherein the plate body has at least one groove located in the heat source contact area and penetrating through the first surface and the second surface, and the three-dimensional thermal conductivity pattern includes at least one thermal conductivity sheet embedded in the at least one groove; and wherein the at least one thermal conductivity sheet is in a shape of a long strip or a mesh.

11. The advanced packaging component according to claim 10, wherein the at least one thermal conductivity sheet is a multi-layer mesh structure, and grids of an upper layer and a lower layer of the multi-layer mesh structure are alternately distributed.

12. The advanced packaging component according to claim 1, wherein the plate body includes an aluminized silicon carbide substrate and an aluminum skin layer covering the aluminized silicon carbide substrate.

13. The advanced packaging component according to claim 12, wherein the aluminized silicon carbide substrate includes a silicon carbide-based porous ceramic substrate and a solid aluminum-based metal infiltrated and filled in pores of the silicon carbide-based porous ceramic substrate.

14. The advanced packaging component according to claim 13, wherein the silicon carbide-based porous ceramic substrate is composed of small-sized particles, medium-sized particles, and large-sized particles, and the particle size ratio of the small-sized particles, the medium-sized particles, and the large-sized particles is 1:2-2.5:3-20.

15. The advanced packaging component according to claim 14, wherein the particle size of the small-sized particles ranges from 0.1 μm to 5 μm, the particle size of the medium-sized particles ranges from 2 μm to 10 μm, and the particle size of the large-sized particles ranges from 10 μm to 100 μm.

16. The advanced packaging component according to claim 14, wherein, based on a total weight of the silicon carbide-based porous ceramic substrate, the weight ratio of the small-sized particles, the medium-sized particles, and the large-sized particles is 1:3:4.

17. A manufacturing method of the advanced packaging component with high thermal conductivity as claimed in claim 1, the manufacturing method comprising:
forming the high-rigidity material into a preform, forming the high thermal conductivity material into the three-dimensional thermal conductivity pattern, and arranging the three-dimensional thermal conductivity pattern into the preform; and
pressing and sintering the preform having the three-dimensional thermal conductivity pattern arranged therein.
